(19) United States
(12) Patent Application Publication
(10) Pub. No.: US 2023/0178393 A1
(43) Pub. Date: Jun. 8, 2023

(54) SEMICONDUCTOR MANUFACTURING APPARATUS AND METHOD OF MANUFACTURING SEMICONDUCTOR DEVICE

(71) Applicant: Kioxia Corporation, Tokyo (JP)

(72) Inventors: Junya FUJITA, Nagoya Aichi (JP); Takayuki MATSUI, Kuwana Mie (JP); Seiichi OMOTO, Yokkaichi Mie (JP)

(73) Assignee: Kioxia Corporation, Tokyo (JP)

(21) Appl. No.: 17/837,950

(22) Filed: Jun. 10, 2022

(30) Foreign Application Priority Data
Dec. 6, 2021 (JP) 2021-197802

(51) Int. Cl. H01L 21/67; C23C 16/455

(52) U.S. Cl. CPC H01L 21/67109; C23C 16/45548; H01L 21/67248

(57) ABSTRACT

In one embodiment, a semiconductor manufacturing apparatus includes a container configured to contain a substrate, a heater configured to heat the substrate contained in the container, and an injector configured to feed gas to the substrate contained in the container. Furthermore, the injector includes a first layer having a tubular shape, and a second layer provided on a surface of the first layer, and having an emissivity of 0.5 or less.

### CROSS REFERENCE TO RELATED APPLICATION

This application is based upon and claims the benefit of priority from the prior Japanese Patent Application No. 2021-197802, filed on Dec. 6, 2021, the entire contents of which are incorporated herein by reference.

### FIELD

Embodiments described herein relate to a semiconductor manufacturing apparatus and a method of manufacturing a semiconductor device.

### BACKGROUND

When gas is fed from an injector to a substrate to form a film on the substrate, the state of the gas may change before the gas reaches the substrate.

### BRIEF DESCRIPTION OF THE DRAWINGS

FIG. 1 is a vertical cross-sectional view showing a structure of a semiconductor manufacturing apparatus of a first embodiment;

FIG. 2 is a horizontal cross-sectional view showing the structure of the semiconductor manufacturing apparatus of the first embodiment;

FIGS. 3A and 3B are horizontal cross-sectional views showing structures of semiconductor manufacturing apparatuses of a first modification and a second modification of the first embodiment;

FIGS. 4A and 4B are vertical cross-sectional views showing structures of semiconductor manufacturing apparatuses of a third modification and a fourth modification of the first embodiment;

FIGS. 5A and 5B are a vertical cross-sectional view and a horizontal cross-sectional view showing a structure of a semiconductor manufacturing apparatus of a fifth modification of the first embodiment;

FIG. 6 is a vertical cross-sectional view showing a structure of a semiconductor manufacturing apparatus of a second embodiment;

FIG. 7 is a horizontal cross-sectional view showing the structure of the semiconductor manufacturing apparatus of the second embodiment; and

FIGS. 8 to 12 are vertical cross-sectional views showing a method of manufacturing a semiconductor device of a third embodiment.

### DETAILED DESCRIPTION

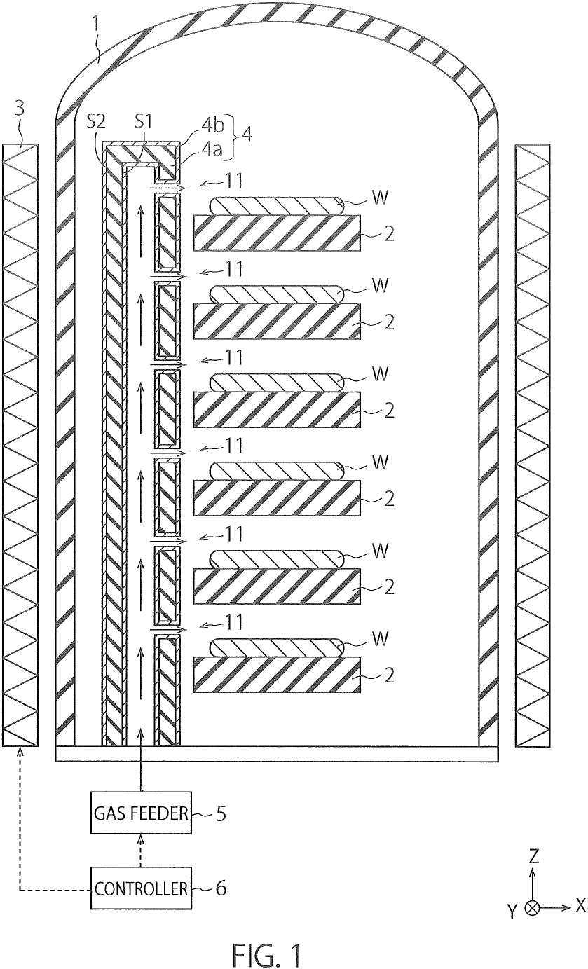

Embodiments will now be explained with reference to the accompanying drawings. In FIGS. 1 to 12, the same components are designated by the same reference numerals and characters, and duplicate description will be omitted.

In one embodiment, a semiconductor manufacturing apparatus includes a container configured to contain a substrate, a heater configured to heat the substrate contained in the container, and an injector configured to feed gas to the substrate contained in the container. Furthermore, the injector includes a first layer having a tubular shape, and a second layer provided on a surface of the first layer, and having an emissivity of 0.5 or less.

### First Embodiment

FIG. 1 is a vertical cross-sectional view showing a structure of a semiconductor manufacturing apparatus of a first embodiment.

The semiconductor manufacturing apparatus of the present embodiment is, for example, a CVD (Chemical Vapor Deposition) apparatus such as an ALD (Atomic Layer Deposition) apparatus. As shown in FIG. 1, the semiconductor manufacturing apparatus of the present embodiment is a batch processing apparatus capable of simultaneously processing a plurality of wafers W. Each wafer W is an example of the substrate.

The semiconductor manufacturing apparatus of the present embodiment includes a tube 1 as an example of the container, at least one boat 2, a heater 3, an injector 4, a gas feeder 5, and a controller 6. The injector 4 includes a plurality of holes 11.

FIG. 1 shows X, Y, and Z directions perpendicular to each other. In this specification, the +Z direction is referred to as an upward direction, and the -Z direction is referred to as a downward direction. The -Z direction may be the same as the gravity direction, or may not be the same as the gravity direction.

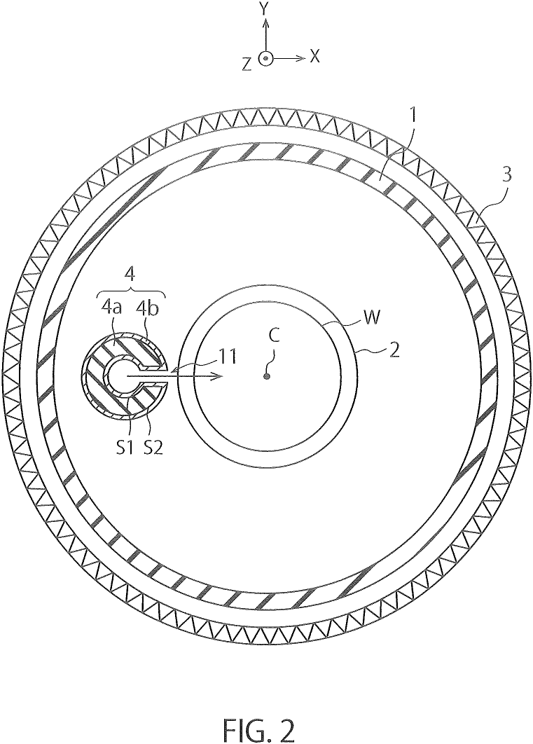

Hereinafter, details of the semiconductor manufacturing apparatus of the present embodiment will be described with reference to FIG. 1. In this description, FIG. 2 is also referred to as appropriate. FIG. 2 is a horizontal cross-sectional view showing the structure of the semiconductor manufacturing apparatus of the first embodiment. FIG. 2 shows an XY cross section passing through any of the holes 11 shown in FIG. 1.

The tube 1 is, for example, a quartz tube made of quartz. The boat 2 has a plurality of slots to allow a plurality of wafers W to be placed, and each slot has one wafer W placed thereon. In FIG. 1, each wafer W is contained in the tube 1 and placed in a corresponding slot of the boat 2. In FIG. 2, the wafer W is placed on the boat 2 so that the center of the wafer W and the center of the boat 2 are aligned in the Z direction. A point C in FIG. 2 indicates an axis passing through the center of the wafer W and the center of the boat 2.

The heater 3 heats each wafer W contained in the tube 1. The heater 3 of the present embodiment is provided outside the tube 1, and is arranged near the outer side face of the tube 1. The heater 3 shown in FIGS. 1 and 2 has a tubular shape surrounding the tube 1, but may have other shapes. Each wafer W is heated by, for example, heat or electromagnetic waves generated by the heater 3.

The injector 4 feeds gas to each wafer W contained in the tube 1. The injector 4 of the present embodiment includes many holes 11, and the number, hole diameter and spacing of these holes 11 are set to values that can evenly feed gas to each wafer W. The injector 4 of the present embodiment is provided inside the tube 1 and is arranged near the inner side face of the tube 1. The injector 4 includes, for example, a base material 4a as an example of the first layer and a protective film 4b as an example of the second layer.

The base material 4a has a tubular shape extending in the Z direction. Therefore, the base material 4a forms a tube having an inner peripheral face and an outer peripheral face. Each hole 11 is provided on the side face of the tube and communicates with the inside of the tube. As shown by arrows in FIGS. 1 and 2, the above-mentioned gas passes through the injector 4 so as to pass through the inside of this tube, and is discharged from the holes 11 to the wafers W. The base material 4a is, for example, an insulator. The base material 4a of the present embodiment is made of quartz.

The protective film 4b is formed on a surface of the base material 4a. As shown in FIGS. 1 and 2, the protective film 4b of the present embodiment is formed on the entire surface of the base material 4a, and is therefore formed on the inner peripheral face and the outer peripheral face of the base material 4a. The protective film 4b of the present embodiment is made of a material having a low emissivity, so that it is unlikely to radiate heat. The emissivity of the protective film 4b of the present embodiment is, for example, 0.5 or less. The protective film 4b is, for example, a metal layer such as a W (tungsten) layer. Further details of the emissivity of the protective film 4b will be described later.

The injector 4 shown in FIGS. 1 and 2 is drawn in a size larger than the actual size to make the base material 4a and the protective film 4b easily seen.

The gas feeder 5 can feed various types of gas to the injector 4. The gas fed from the gas feeder 5 is, for example, a source gas for forming a film on each wafer W. For example, when a SiO₂ film (silicon oxide film) is formed on each wafer W, the gas feeder 5 feeds a Si source gas including Si (silicon) and an O source gas including O (oxygen) to the injector 4. Examples of Si source gas include a silane gas (e.g., SiH₄ and Si₂H₆), a chlorosilane gas (e.g., SiH₃Cl, SiH₂Cl₂, SiHCl₃, and SiCl₄), an aminosilane gas (e.g., BTBAS (Bis Tertiary-Butylaminosilane)), where: H represents hydrogen, Cl represents chlorine. Examples of O source gas include O₃ (ozone) gas. For example, SiH₄ gas and O₃ gas are fed from the gas feeder 5 to each wafer W via the injector 4, so that a SiO₂ film is formed on each wafer W.

The gas feeder 5 may feed a gas other than the source gas to the injector 4. Examples of such gas include inert gas such as rare gases and N₂ (nitrogen) gas. Further, the gas feeder 5 may generate a gas by a chemical reaction and feed the gas to the injector 4, or may generate a gas from the liquid by vaporization, and feed the gas to the injector 4.

The controller 6 controls various operation of the semiconductor manufacturing apparatus of the present embodiment. For example, the controller 6 controls rotation of the boat 2, on/off of the heater 3, heat generation amount of the heater 3, on/off of the gas fed from the gas feeder 5, the type of the gas fed from the gas feeder 5, the flow rate of the gas fed from the gas feeder 5, and the like.

Next, further details of the semiconductor manufacturing apparatus of the present embodiment will be described with reference to FIG. 1.

In forming SiO₂ films on the wafers W, it is desirable to feed Si source gas and O source gas from the injector 4 to the wafers W while the wafers W are heated in a high temperature with the heater 3. The reason is to lower wet etching rates and shrinkage rates of the SiO₂ films formed on the wafers W.

However, if the O₃ gas, which is the O source gas, is heated, the O₃ gas may be inactivated. Specifically, the O₃ gas may change to the O₂ gas. For example, when the injector 4 is heated by the heater 3, the O₃ gas is heated in the injector 4 and inactivated. The injector 4 has a long size in the Z direction and is arranged near the heater 3, so that the O₃ gas is likely to be heated in the injector 4.

Therefore, the injector 4 of the present embodiment is formed by covering the base material 4a with the protective film 4b. The protective film 4b of the present embodiment has a low emissivity of 0.5 or less, and it is therefore unlikely to radiate heat. Materials with low emissivity is unlikely to absorb heat and electromagnetic waves. Therefore, the protective film 4b of the present embodiment is unlikely to absorb heat and electromagnetic waves from the heater 3, and it is therefore unlikely to be heated by the heater 3. This causes the present embodiment to make it possible to form the injector 4 including the base material 4a and the protective film 4b, and thereby to prevent the injector 4 from being heated by the heater 3. This makes it possible to prevent the O₃ gas from being heated in the injector 4, and to prevent the O₃ gas from being inactivated.

In the present embodiment, such an injector 4 feeds Si source gas and O source gas to each wafer W while the heater 3 heats each wafer W. Therefore, while the heater 3 heats each wafer W, the temperature inside the injector 4 is lower than the temperature of each wafer W. For example, the temperature of the space inside the injector 4 is lower than the temperature of the space near each wafer W inside the tube 1. This makes it possible to prevent the O₃ gas in the injector 4 from being inactivated. For example, if the temperature of each wafer W is higher than 500° C. (e.g., about 550° C.), the temperature inside the injector 4 is kept lower than 500° C. (e.g., about 450° C.).

When the injector 4 includes the base material 4a but does not include the protective film 4b, each wafer W may be heated at a low temperature. In this case, the temperature inside the injector 4 is also low, so that the O₃ gas can be prevented from being inactivated. However, if each wafer W is heated at a low temperature, a high-quality SiO₂ film cannot be formed. On the other hand, when the injector 4 includes the base material 4a and the protective film 4b, the temperature inside the injector 4 is low, but each wafer W can be heated in a high temperature. This makes it possible to form a high-quality SiO2 film in a short time while preventing the O₃ gas from being inactivated.

Such an effect can also be obtained when a film other than SiO₂ film is formed or when a gas other than O₃ gas is used. For example, when a source gas is heated above a certain temperature in the injector 4, a CVD reaction occurs in the injector 4, and a CVD film is deposited on the surface of the injector 4. Since the pressure inside the injector 4 is higher than that in the other regions in the tube 1, the deposition speed of the CVD film is high. Therefore, the inner diameters of the injector 4 and the holes 11 become smaller due to the CVD film, which may cause a problem in gas feeding, or may break the injector 4 due to the stress of the CVD film, requiring periodic replacement of the injector 4. However, if this source gas is fed to each wafer W from the injector 4 of the present embodiment, the deposition speed of the CVD film in the injector 4 can be reduced. This makes it possible to achieve both the film quality and film productivity.

The protective film 4b may be a metal layer other than W layer, or a film other than a metal layer. For example, the protective film 4b may be formed of a single metal or a metal compound. An example of the former protective film 4b is a W layer or a metal layer including one kind of metal element other than W element. Examples of the latter protective film 4b include a metal layer including W element and other elements (that may be a metal element or a non-metal element).

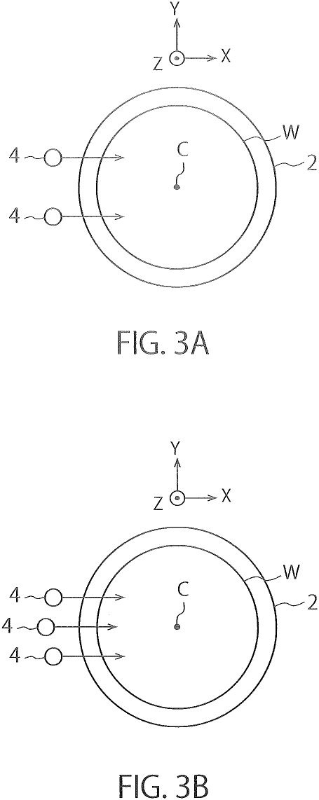

FIGS. 3A and 3B are horizontal cross-sectional views showing structures of semiconductor manufacturing apparatuses of a first modification and a second modification of the first embodiment.

As shown in FIGS. 3A and 3B, the semiconductor manufacturing apparatuses of the present embodiment may include a plurality of injectors 4. The semiconductor manufacturing apparatus shown in FIG. 3A includes two injectors 4. The semiconductor manufacturing apparatus shown in FIG. 3B includes three injectors 4. The structure and operation of each injector 4 shown in FIGS. 3A and 3B are the same as those of the injector 4 shown in FIGS. 1 and 2. In FIGS. 3A and 3B, the Si source gas and the O source gas may be fed from the same injectors 4 or may be fed from different injectors 4.

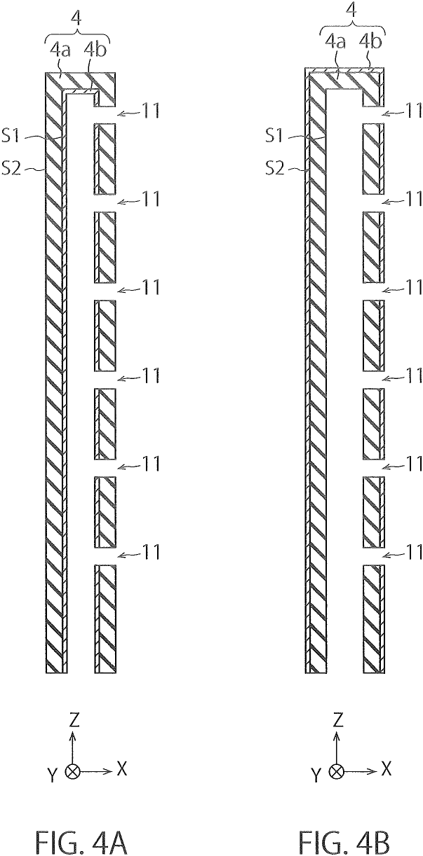

FIGS. 4A and 4B are vertical cross-sectional views showing structures of semiconductor manufacturing apparatuses of a third modification and a fourth modification of the first embodiment.

As shown in FIGS. 4A and 4B, the injectors 4 of the present embodiment each may include the protective film 4b only on a part of the surface of the base material 4a. In the injector 4 shown in FIG. 4A, the protective film 4b is formed only on the inner peripheral face of the base material 4a, out of the inner peripheral face and the outer peripheral face of the base material 4a. In the injector 4 shown in FIG. 4B, the protective film 4b is formed only on the outer peripheral face of the base material 4a, out of the inner peripheral face and the outer peripheral face of the base material 4a. However, to effectively prevent the O₃ gas from being inactivated, the protective film 4b is desirably formed on the inner peripheral face and the outer peripheral face of the base material 4a.

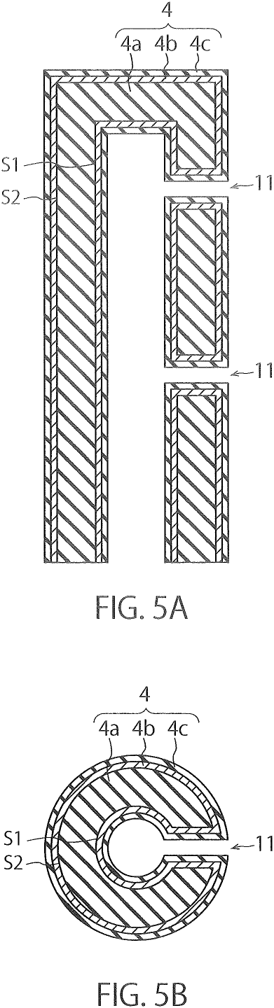

FIGS. 5A and 5B are a vertical cross-sectional view and a horizontal cross-sectional view showing a structure of a semiconductor manufacturing apparatus of a fifth modification of the first embodiment.

As shown in FIGS. 5A and 5B, an injector 4 of the present embodiment may include a base material 4a, a protective film 4b, and additionally a protective film 4c. In FIGS. 5A and 5B, the protective film 4c is formed on the surface of the base material 4a via the protective film 4b. In FIGS. 5A and 5B, the protective film 4c is formed on both the inner peripheral face and the outer peripheral face of the base material 4a. However, it may be formed on only one of the inner peripheral face and the outer peripheral face of the base material 4a. Further, the protective film 4c may be provided on an injector 4 shown in FIG. 4A or FIG. 4B. The protective film 4c is, for example, a non-metal layer such as a SiO₂ film. The protective film 4c is an example of a third layer.

When the protective film 4b is a metal layer (for example, W layer), the metal atoms (for example, W atoms) included in the protective film 4b may contaminate the inside of the tube 1. Then, the protective film 4b shown in FIGS. 5A and 5B is covered with the protective film 4c. This makes it possible to prevent the protective film 4b from being a contamination source for the tube 1.

Therefore, the protective film 4c is desirably made of a material that does not contaminate the inside of the tube 1, or a material that is unlikely to contaminate the inside of the tube 1. For example, if the protective film 4c is a non-metal layer, the protective film 4c does not include metal atoms (excluding impurity atoms), so that the protective film 4c can be prevented from being a contamination source for the tube 1. Further, if the protective film 4c is a SiO₂ film, the SiO₂ film is a film included in many semiconductor devices, so that the protective film 4c can be prevented from being a contamination source of the tube 1.

If a metal layer does not contaminate the inside of the tube 1 or it is unlikely to contaminate the inside of the tube 1, the protective film 4c may be the metal oxide film. An example of such a metal oxide film is an Al₂O₃ film (aluminum oxide film).

Further, the protective film 4c may be made of a material having a low emissivity, or may be made of a material having a high emissivity. For example, the emissivity of the protective film 4c may be 0.5 or less, or may be larger than 0.5. However, when the emissivity of the protective film 4c is high, the protective film 4c may promote the O₃ gas to be inactivated, so that the protective film 4c is desirably thin. For example, the protective film 4c may have about the same thickness as the protective film 4b, or may be thinner than the protective film 4b.

As described above, the injector 4 of the present embodiment includes the protective film 4b having a low emissivity on the surface of the base material 4a. Therefore, the present embodiment makes it possible to feed a gas suitable for the wafers W when the films are formed on the wafers W. For example, this can prevent the O₃ gas for forming the SiO₂ film on the wafers W from being inactivated.

### Second Embodiment

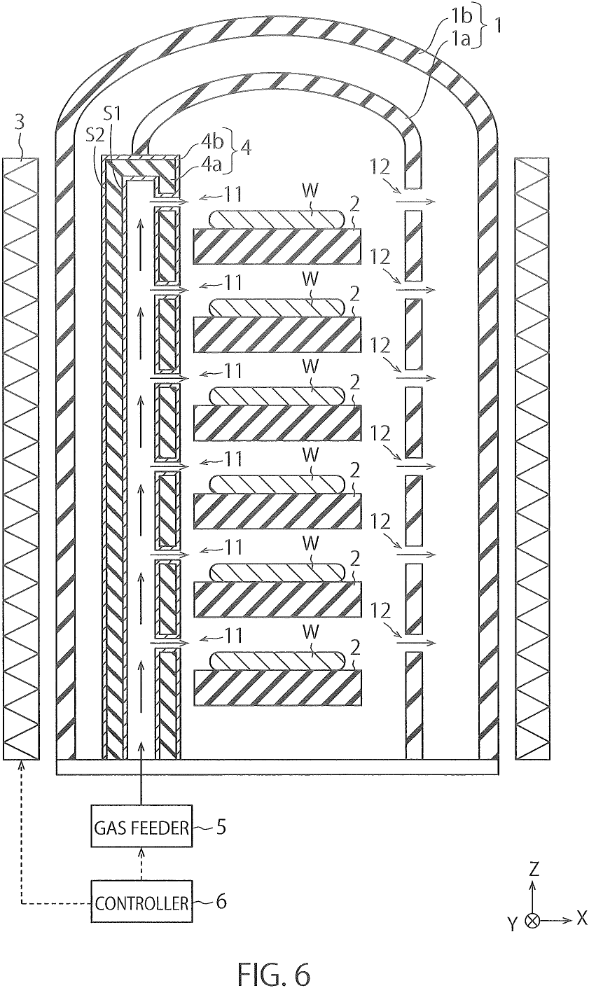

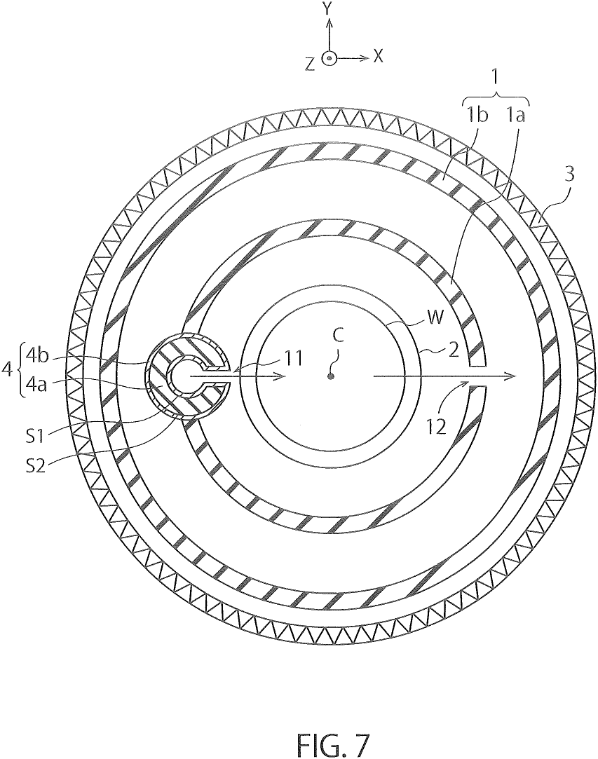

FIGS. 6 and 7 are a vertical cross-sectional view and a horizontal cross-sectional view showing a structure of a semiconductor manufacturing apparatus of a second embodiment, respectively. FIG. 7 shows an XY cross section passing through any of holes 11 shown in FIG. 6.

The semiconductor manufacturing apparatus of the present embodiment includes similar components as in the semiconductor manufacturing apparatus of the first embodiment. However, the tube 1 of the present embodiment includes: an inner tube 1a for containing a plurality of wafers W on the boats 2; and an outer tube 1b for containing the inner tube 1a. Each of the inner tube 1a and the outer tube 1b is, for example, a quartz tube. The inner tube 1a is an example of a first container, and the outer tube 1b is an example of a second container.

In the present embodiment, a heater 3 is provided outside the outer tube 1b, and an injector 4 is provided inside the inner tube 1a. Note that the injector 4 shown in FIGS. 6 and 7 is drawn in a size larger than the actual size, so that it is drawn not inside the inner tube 1a but at a position overlapping the inner tube 1a. The injector 4 may be in contact with the inner tube 1a, or it may not be in contact with the inner tube 1a.

FIG. 7 shows how gas is discharged from a hole 11 of the injector 4. The gas discharged from the hole 11 is fed to the wafer W and used to form a film on the wafer W. The gas remaining without contributing to the formation of the film and the gas generated during the formation of the film are discharged from a vent 12 provided in the inner tube 1a. Then, the gases pass between the inner tube 1a and the outer tube 1b, and they are discharged to the outside of the outer tube 1b.

As described above, the injector 4 including the base material 4a and the protective film 4b can also be applied to the tube 1 including the inner tube 1a and the outer tube 1b.

### Third Embodiment

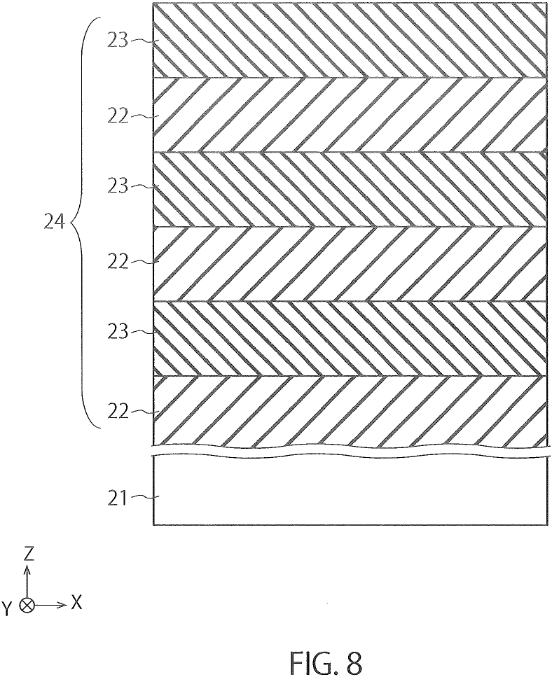

FIGS. 8 to 12 are vertical cross-sectional views showing a method of manufacturing a semiconductor device of a third embodiment. The semiconductor device of the present embodiment is, for example, a three-dimensional semiconductor memory.

In the steps shown in FIGS. 8 to 12, various SiO₂ films are formed. At least one of these SiO₂ films may be formed in the semiconductor manufacturing apparatus of the first embodiment or the second embodiment. Further, the other films shown in FIGS. 8 to 12 may also be formed in the semiconductor manufacturing apparatus of the first embodiment or the second embodiment.

First, a substrate 21 is prepared (FIG. 8). The substrate 21 is, for example, a semiconductor substrate such as a Si substrate. The substrate 21 of the present embodiment corresponds to a specific example of each wafer W of the first embodiment or the second embodiment.

Next, a plurality of insulating layers 22 and a plurality of sacrificial layers 23 are alternately formed on the substrate 21 (FIG. 8). As a result, a laminated film 24 including the insulating layers 22 and the sacrificial layers 23 are formed on the substrate 21. Each insulating layer 22 is, for example, a SiO₂ film. Each sacrificial layer 23 is, for example, a SiN film (silicon nitride film).

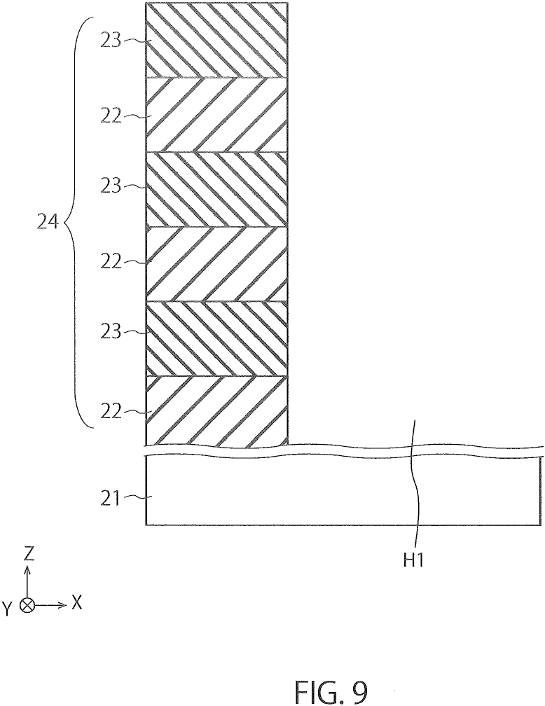

Next, a plurality of memory holes H1 are formed in the laminated film 24 by photolithography and RIE (Reactive Ion Etching) (FIG. 9). FIG. 9 shows one of these memory holes H1.

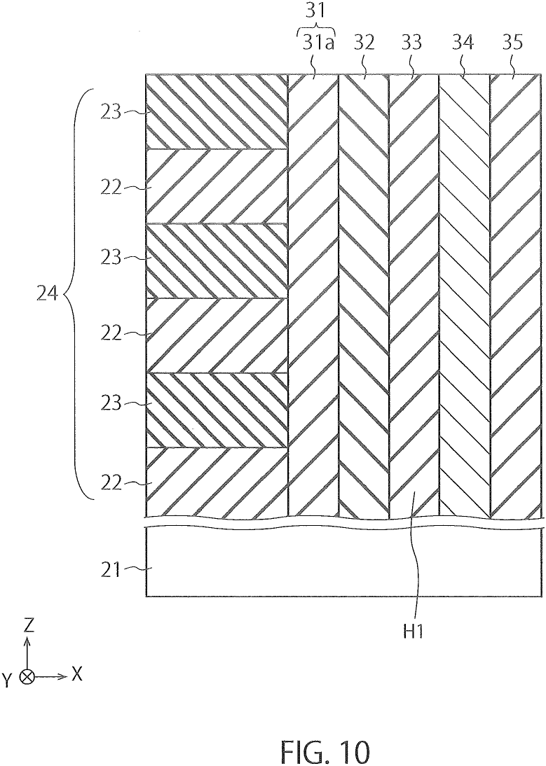

Next, an insulator 31a of a block insulator 31, a charge trap layer 32, a tunnel insulator 33, a channel semiconductor layer 34, and a core insulator 35 are sequentially formed in each memory hole H1 (FIG. 10). The insulator 31a is, for example, a SiO2 film. The charge trap layer 32 is, for example, a SiN film. The tunnel insulator 33 is, for example, a SiO₂ film or a SiON film (silicon oxynitride film). The channel semiconductor layer 34 is, for example, a polysilicon layer. The core insulator 35 is, for example, a SiO2 film.

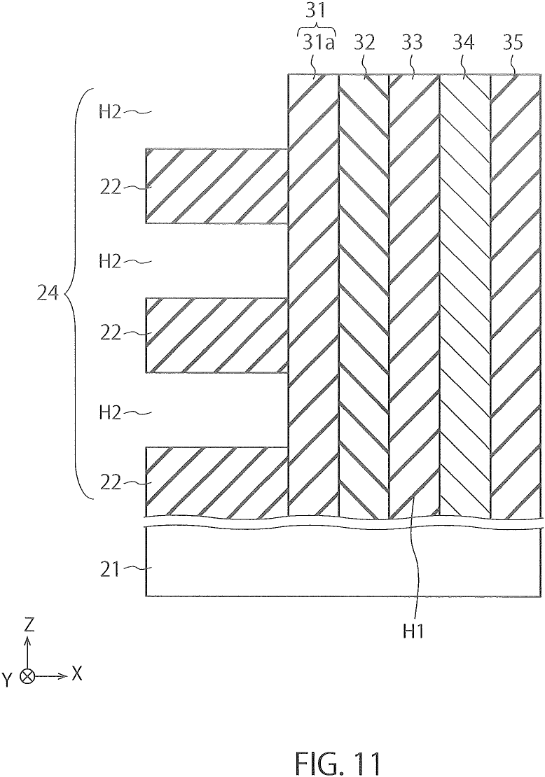

Next, a slit (not shown) is formed in the laminated film 24, and wet etching from the slit removes each sacrificial layer 23 (FIG. 11). As a result, a plurality of cavities H2 are formed in the laminated film 24.

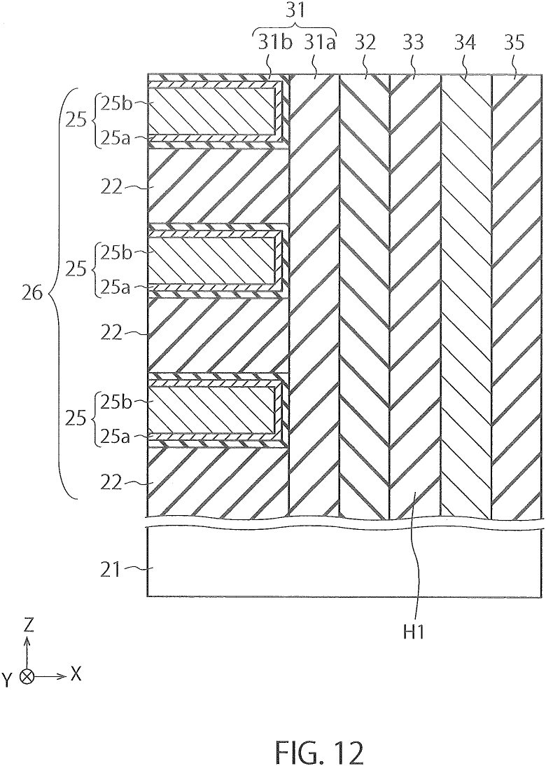

Next, an insulator 31b of the block insulator 31, a barrier metal layer 25a, and an electrode material layer 25b are sequentially formed in each cavity H2 (FIG. 12). As a result, a laminated film 26 including a plurality of insulating layers 22 and a plurality of electrode layers 25 is formed on the substrate 21. In other words, each sacrificial layer 23 is replaced with one electrode layer 25, and the laminated film 24 is replaced with the laminated film 26. Each electrode layer 25 is formed in one cavity H2 via an insulator 31b, and includes a barrier metal layer 25a and an electrode material layer 25b in this order. The insulator 31b is, for example, an Al₂O₃ film. The barrier metal layer 25a is, for example, a TiN film (titanium nitride film). The electrode material layer 25b is, for example, a W (tungsten) layer.

After that, various plug layers, interconnect layers, inter-layer dielectric films, and the like are formed on the substrate 21. In this way, the semiconductor device of the present embodiment is manufactured.

In forming a film on the substrate 21, the present embodiment makes it possible to form a film on the substrate 21 in the semiconductor manufacturing apparatus of the first embodiment or the second embodiment, and thereby feed a suitable gas to the substrate 21. For example, this can prevent O₃ gas for forming the SiO₂ film on the substrate 21 from being inactivated.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A semiconductor manufacturing apparatus comprising:
a container configured to contain a substrate;
a heater configured to heat the substrate contained in the container; and
an injector configured to feed gas to the substrate contained in the container,
wherein the injector includes:
a first layer having a tubular shape, and
a second layer provided on a surface of the first layer, and having an emissivity of 0.5 or less.

2. The apparatus of claim 1, wherein the first layer includes an insulator.

3. The apparatus of claim 1, wherein the second layer includes a metal layer.

4. The apparatus of claim 1, wherein the second layer is provided on an inner peripheral face and an outer peripheral face of the first layer.

5. The apparatus of claim 1, wherein the second layer is provided only on an inner peripheral face of the first layer, or only on an outer peripheral face of the first layer, out of the inner peripheral face and the outer peripheral face of the first layer.

6. The apparatus of claim 1, wherein the injector further includes a third layer provided on the surface of the first layer via the second layer.

7. The apparatus of claim 6, wherein the third layer includes a non-metal layer.

8. The apparatus of claim 1, wherein the injector includes a hole that discharges the gas to the substrate.

9. The apparatus of claim 8, wherein
the container can contain a plurality of substrates, and
the injector includes a plurality of holes that discharge the gas on the plurality of substrates.

10. The apparatus of claim 1, wherein
the heater is provided outside the container, and
the injector is provided inside the container.

11. The apparatus of claim 1, wherein a temperature inside the injector is lower than a temperature of the substrate while the heater heats the substrate.

12. The apparatus of claim 1, wherein the container includes a first container configured to contain the substrate, and a second container configured to contain the first container.

13. A semiconductor manufacturing apparatus comprising:
a container configured to contain a substrate;
a heater configured to heat the substrate contained in the container; and
an injector configured to feed gas to the substrate contained in the container, wherein the injector includes:
a first layer having a tubular shape, and
a second layer provided on a surface of the first layer, and including a metal layer.

14. The apparatus of claim 13, wherein the first layer includes an insulator.

15. The apparatus of claim 13, wherein the second layer has an emissivity of 0.5 or less.

16. A method of manufacturing a semiconductor device, comprising:
containing a substrate in a container;
heating the substrate contained in the container by a heater; and
feeding gas from an injector to the substrate contained in the container to form a film on the substrate,
wherein the injector includes:
a first layer having a tubular shape, and
a second layer provided on a surface of the first layer, and having an emissivity of 0.5 or less.

17. The method of claim 16, wherein the gas includes a source gas that forms the film on the substrate.

18. The method of claim 17, wherein the source gas includes Si (silicon).

19. The method of claim 17, wherein the source gas includes O (oxygen).

20. The method of claim 16, wherein the gas includes O₃ (ozone) gas.
